(19) United States
(12) Patent Application Publication
(10) Pub. No.: US 2015/0364585 A1
(43) Pub. Date: Dec. 17, 2015

(54) POWER SEMICONDUCTOR DEVICE

(71) Applicant: Samsung Electro-Mechanics Co., Ltd., Suwon (KR)

(72) Inventors: In Hyuk SONG, Suwon (KR); Dong Soo SEO, Suwon (KR); Ji Hye KIM, Suwon (KR); Chang Su JANG, Suwon (KR); Jae Hoon PARK, Suwon (KR)

(73) Assignee: Samsung Electro-Mechanics Co., Ltd., Suwon (KR)

(21) Appl. No.: 14/470,355

(22) Filed: Aug. 27, 2014

(30) Foreign Application Priority Data
Jun. 11, 2014 (KR) 10-2014-0070611

(51) Int. Cl. H01L 29/739; H01L 29/08; H01L 29/417; H01L 29/10

(52) U.S. Cl. CPC H01L 29/7395; H01L 29/1095; H01L 29/0804; H01L 29/0821; H01L 29/41708

(57) ABSTRACT

A power semiconductor device may include: an n-drift part; a gate disposed in an upper portion of the n-drift part; an active part disposed to be in contact with the gate; an emitter part disposed in the active part and disposed to be in contact with the gate; an inactive part disposed to be spaced apart from the active part; a floating part disposed in the inactive part; and a dummy gate disposed to surround the inactive part in order to prevent a hole pass between the active part and the inactive part.

### CROSS-REFERENCE TO RELATED APPLICATION

This application claims the benefit of Korean Patent Application No. 10-2014-0070611 filed on Jun. 11, 2014, with the Korean Intellectual Property Office, the disclosure of which is incorporated herein by reference.

### BACKGROUND

The present disclosure relates to a power semiconductor device.

When a switch-off operation is performed in a power semiconductor device, a current flow should be blocked, and in order to effectively block a current, a channel needs to be formed as small as possible. In this case, gates that contribute to forming a channel are merely a portion of the total number of gates, and gates that do not contribute to forming the channel may cause parasitic capacitance. Parasitic capacitance may increase a delay time of a switching operation, increase conduction loss, and cause an oscillation in a gate signal at the time of determining whether or not a short circuit has occurred, thereby causing current oscillations and causing defects in power semiconductor devices.

### RELATED ART DOCUMENT

(Patent Document 1) Korean Patent Laid-Open Publication No. 10-2013-0035399

### SUMMARY

An exemplary embodiment in the present disclosure may provide a power semiconductor device capable of decreasing generation of parasitic capacitance, operating at a high withstand voltage, and decreasing conduction loss.

According to an exemplary embodiment in the present disclosure, a power semiconductor device may include a gate, an active part disposed to be in contact with the gate, an emitter part disposed in the active part and disposed to be in contact with the gate, a dummy gate disposed to be spaced apart from the gate, an inactive part disposed in a region surrounded by the dummy gate, and a floating part disposed in the inactive part.

The active part may be disposed in a region surrounded by the gate and an interlayer insulating film and an emitter metal layer may be disposed on upper portions of the floating part and the gate. A collector electrode, a p-collector layer, an n-buffer layer may be disposed below the n-drift part.

According to an exemplary embodiment in the present disclosure, a power semiconductor device may include a first gate disposed to be spaced apart from a first external surface of a dummy gate, a first active part disposed in a region between the first external surface of the dummy gate and the first gate, an inactive part disposed in a region surrounded by an internal surface of the dummy gate, a second gate disposed to be spaced apart from a second external surface of the dummy gate, and a second active part disposed in a region between the second external surface of the dummy gate and the second gate.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a plan view of a power semiconductor device according to an exemplary embodiment in the present disclosure;

FIG. 2 is a cross-sectional view taken along line A-A′ of the power semiconductor device of FIG. 1;

FIG. 3 is a plan view of a power semiconductor device according to another exemplary embodiment in the present disclosure;

FIG. 4 is a cross-sectional view taken along line B-B′ after an interlayer insulating film and an emitter metal layer are disposed on the power semiconductor device of FIG. 3;

FIG. 5 is a plan view of a power semiconductor device according to a third exemplary embodiment in the present disclosure;

FIG. 6 is a cross-sectional view taken along line C-C′ of the power semiconductor device of FIG. 5;

FIG. 7 is a plan view of a power semiconductor device according to a fourth exemplary embodiment in the present disclosure;

FIG. 8 is a cross-sectional view taken along line D-D′ after an interlayer insulating film and an emitter metal layer are disposed on the power semiconductor device of FIG. 7;

FIG. 9 is a plan view of a power semiconductor device according to a fifth exemplary embodiment in the present disclosure;

FIG. 10 is a cross-sectional view taken along line E-E′ of the power semiconductor device of FIG. 9;

FIG. 11 is a plan view of a power semiconductor device according to a sixth exemplary embodiment in the present disclosure; and

FIG. 12 is a cross-sectional view taken along line F-F′ after an interlayer insulating film and an emitter metal layer are disposed on the power semiconductor device of FIG. 11.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

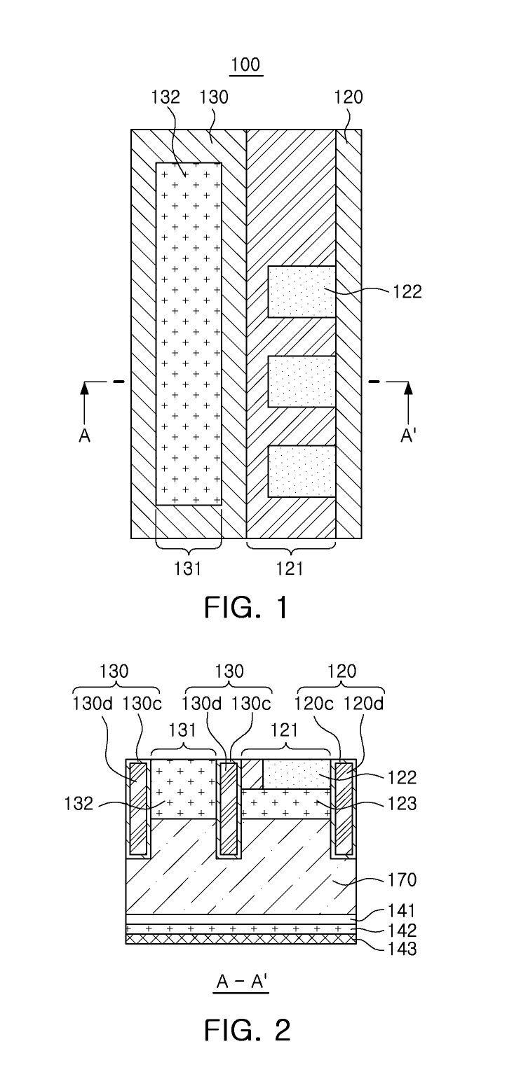

FIG. 1 is a plan view of a power semiconductor device 100 according to an exemplary embodiment in the present disclosure and FIG. 2 is a cross-sectional view taken along line A-A′ of the power semiconductor device 100 of FIG. 1.

Referring to FIGS. 1 and 2, the power semiconductor device 100 according to the present exemplary embodiment may include an n-drift part 170, a gate 120 disposed in an upper portion of the n-drift part 170, an active part 121 disposed to be in contact with the gate 120, an emitter part 122 disposed in the active part 121 and disposed to be in contact with the gate, an inactive part 131 disposed to be spaced apart from the active part 121, a floating part 132 disposed in the inactive part 131, and a dummy gate 130 disposed to surround the inactive part 131 in order to prevent a hole pass between the active part 121 and the inactive part 131.

The n-drift part 170 may be formed by implanting n-type impurities into one surface of a semiconductor substrate using an implantation process or a spreading process. A thickness, shape, and concentration of the n-drift part 170 may have appropriate values determined to obtain a breakdown voltage and an on-resistance required by the power semiconductor device 100, and are not limited to those illustrated in FIG. 2.

The semiconductor substrate on which the n-drift part 170 is disposed may be a silicon substrate, a silicon carbide substrate, or a sapphire substrate, but is not limited thereto.

A collector electrode 143 may be disposed below the n-drift part 170. A p-collector layer 142 may be further disposed between the collector electrode 143 and the n-drift part 170 and an n-buffer layer 141 may be further disposed between the p-collector layer 142 and the n-drift part 170. The p-collector layer 142 into which p-type impurities are implanted may have p-type conductivity. The n-buffer layer 141 in which n-type impurities such as phosphorus (P) or arsenic (As) are implanted may have n-type conductivity and may have a doping concentration higher than that of the n-drift part 170.

The gate 120 may be disposed in the upper portion of the n-drift part 170. In addition, the gate 120 may be disposed in trenches separated at predetermined intervals in the upper portion of the n-drift part 170. An inner surface of the gate 120 may be provided with a gate conductive part 120d in which a conductive material such as polysilicon, or the like is disposed and an external side of the gate 120 may be provided with a gate insulating part 120c in which an insulating material such as a silicon oxide film, or the like is disposed. Electrical short circuits between the gate 120 and the n-drift part 170 may be prevented by the gate insulating part 120c provided on the external surface of the gate 120.

The active part 121 may be disposed in a region adjacent to the gate 120, and the emitter part 122 may be formed in the active part 121 to be in contact with the gate 120. The emitter part 122, which may be an n-type semiconductor having a high concentration of impurities, may be formed by implanting n-type impurities into the active part 121 using an implantation process or a spreading process. Referring to FIGS. 1 and 2, the emitter part 122 is disposed on one surface of the gate 120 to be connected to the gate insulating part 120c, but is not limited thereto. In the case in which the gate 120 and the dummy gate 130 illustrated in FIG. 1 are repeatedly disposed in a lateral direction, since the active part 121 may be disposed on both surfaces of the gate 120, the emitter part 122 may be disposed on one surface or both surfaces of the gate 120.

A region in which the emitter part 122 is not formed in the active part 121 may be a p-type region. In addition, a p-type part 123 may also be formed below the emitter part 122. The p-type part 123 may be formed by implanting p-type impurities into the active part 121 using an implantation process or a spreading process.

Although not illustrated in FIGS. 1 and 2, the gate 120 may be connected to a gate poly bus electrode to thereby form a channel in the active part 121.

The dummy gate 130 may be disposed in a trench disposed to be spaced apart from the trench having the gate 120 disposed in the upper portion of the n-drift part 170. An inner surface of the dummy gate 130 may be provided with a dummy gate conductive part 130d in which a conductive material such as polysilicon, or the like is disposed and an external side of the dummy gate 130 may be provided with a dummy gate insulating part 130c in which an insulating material such as a silicon oxide film, or the like is disposed. Electrical short circuits between the dummy gate 130 and the n-drift part 170 may be prevented by the dummy gate insulating part 130c provided to the external side of the dummy gate 130.

The inactive part 131 may be disposed in a region surrounded by the dummy gate 130. The floating part 132 may be disposed in the inactive part 131, wherein the floating part 132 may be a p-type part. The floating part 132 may be formed by implanting p-type impurities thereinto using an implantation process or a spreading process. Since the inactive part 131 is disposed to be spaced apart from the active part 121, a movement of a hole of the inactive part 131 to the active part 121 may be limited. Therefore, a hole pass caused between the inactive part 131 and the active part 121 may be prevented and conduction loss may be decreased.

In the case in which the floating part 132 is disposed while not being surrounded by the dummy gate 130, there may be a problem with an increase in a withstand voltage. However, since the floating part 132 is surrounded by the dummy gate 130, increasing the withstand voltage may be more effective.

In the power semiconductor device 100 according to an exemplary embodiment shown in FIGS. 1 and 2, in order for the inactive part 131 and the active part 121 to be disposed electrically independently from each other, the dummy gate 130 disposed on one surface of the inactive part 131 may be disposed in parallel with the gate 120. However, the disposition of the dummy gate 130 and the gate is not limited thereto. The active part 121 may be disposed between the dummy gate 130 and the gate 120. Since the inactive part 131 is disposed in the region surrounded by the dummy gate, the active part 121 and the inactive part 131 may be disposed to be spaced apart from each other.

Depths in a width direction of the n-drift part 170 of the gate 120 and the dummy gate 130 may be disposed to be deeper than depths in which the p-type part 123 of the active part 121 disposed to be adjacent to the gate 120 and the floating part 132 of the inactive part 131 disposed to be surrounded by the dummy gate 130 are disposed. By the above-mentioned configuration, the active part 121 and the inactive part 131 may be blocked from each other.

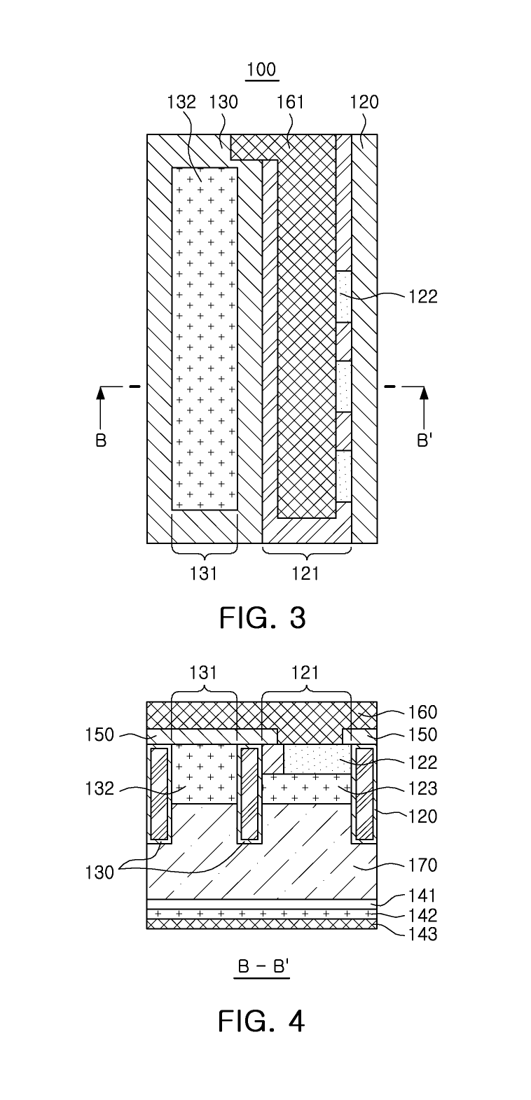

FIG. 3 is a plan view of a power semiconductor device 100 according to another exemplary embodiment of the present disclosure and FIG. 4 is a cross-sectional view taken along lineline B-B′ after an interlayer insulating film 150 and an emitter metal layer 160 are disposed on the power semiconductor device 100 of FIG. 3.

Specifically, FIG. 3 is a plan view illustrating an emitter metal layer connecting part 161 that is a region having the emitter metal layer 160 connected thereto in the power semiconductor device 100 in which the gate 120, the dummy gate 130, the active part 121, and the inactive part 131 are disposed.

Referring to FIGS. 3 and 4, the power semiconductor device 100 according to an exemplary embodiment of the present disclosure may have an interlayer insulating film 150 disposed on an upper portion of the gate 120 to thereby prevent a connection between the gate 120 and the emitter metal layer 160. Since the interlayer insulating film 150 is disposed on a portion of the upper portion of the dummy gate 130, the portion of the upper portion of the dummy gate 130 may be connected to the emitter metal layer 160. Since the interlayer insulating film 150 is disposed on a portion of an upper portion of the active part 121, the portion of the upper portion of the active part 121 may be connected to the emitter metal layer 160.

The interlayer insulating film 150 may be disposed on the portion of the upper portion of the dummy gate 130. Accordingly, the portion of the dummy gate 130 may be electrically connected to the emitter metal layer 160. Since the dummy gate 130 and the emitter metal layer 160 are partially connected to each other, the dummy gate 130 and the floating part 132 may not affect capacitance of the gate 120. By the above-mentioned configuration, the capacitance may be decreased and the conduction loss may be decreased.

The power semiconductor device 100 according to an exemplary embodiment of the present disclosure may have a PNP transistor structure formed by the p-type part 123, the n-drift part 170, the n-buffer layer 141, and the p-collector layer 142. An operation principle of the power semiconductor device 100 according to an exemplary embodiment of the present disclosure will be described based on the PNP transistor structure.

The gate 120 may be connected to a gate poly bus electrode. Once a current is applied to the gate poly bus electrode, the emitter metal layer 160, and the collector electrode 143, the current flows in the gate 120 through the gate poly bus electrode, such that a gate voltage may be formed between the gate 120 and the emitter metal layer 160 and a collector voltage may be applied between the gate 120 and the collector electrode 143. In this case, a portion of the p-type part 123 may be transformed into an n-type to thereby form a channel. The current flows from the n-drift part 170 to the emitter metal layer 160 through the channel. Once a concentration of electrons in the n-drift part 170 is increased, holes in the p-collector layer 142 may enter the n-drift part 170, thereby completing a switch-on operation.

Once the current flowing through the gate poly bus electrode is blocked, the voltage between the gate 120 and the emitter metal layer 160 becomes zero. The channel that was formed in the active part 121 may be again transformed into a p-type to thereby remove the channel, and the current flow from the n-drift part 170 to the emitter metal layer 160 may also be stopped, thereby completing a switch-off operation.

According to an exemplary embodiment of the present disclosure, since the channel is formed in the active part 121 disposed to be adjacent to the gate 120 and the channel is not formed in the inactive part 131 surrounded by the dummy gate 130, the gate 120 that contributes to forming the channel and the dummy gate 130 that does not contribute to forming the channel may be distinguished from each other. Since the gate 120 and the dummy gate 130 are independently formed, parasitic capacitance caused by the gate that does not contribute to forming the channel may be prevented.

In addition, the dummy gate 130 is electrically connected to the emitter metal layer 160, wherein since the active part 121 and the inactive part 131 are electrically independent from each other, a structure blocking a hole pass between the active part 121 and the inactive part 131 may be formed. The conductor loss may be decreased by blocking the hole pass as described above.

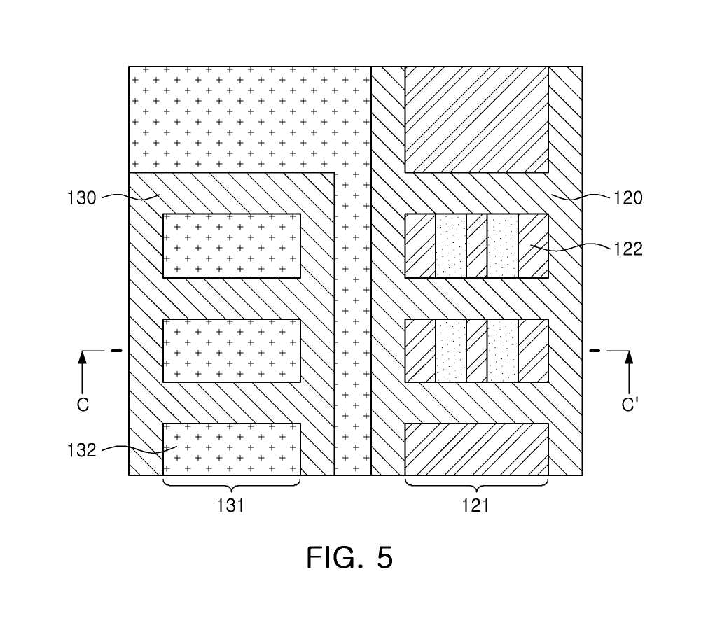

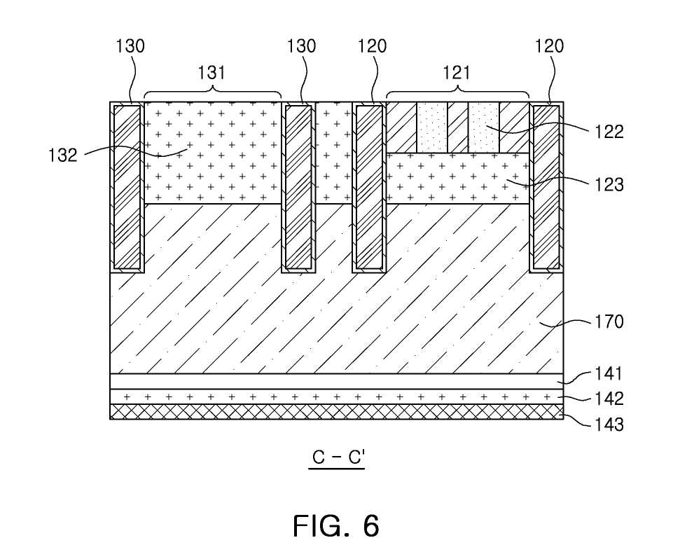

FIG. 5 is a plan view of a power semiconductor device 100 according to a third exemplary embodiment of the present disclosure and FIG. 6 is a cross-sectional view taken along line C-C′ of the power semiconductor device 100 of FIG. 5.

Referring to FIGS. 5 and 6, the power semiconductor device 100 according to an exemplary embodiment of the present disclosure may have the active part 121 disposed in a region surrounded by the gate 120.

Since the active part 121 is surrounded by the gate 120, it is not connected to the dummy gate 130, such that the active part 121 and the inactive part 131 may be clearly distinguished and the hole pass may be more effectively blocked.

As illustrated in FIG. 5, a plurality of active parts 121 and a plurality of inactive parts 131 may be disposed in the same direction. The active part 121 and the inactive part 131 need to be independently disposed, but the disposition thereof is not limited to an example illustrated in FIG. 5. In addition, areas that are occupied by the active part 121 and the inactive part 131 and the number of active parts 121 and inactive parts 131 disposed may be variously changed by considering current capacity, parasitic capacitance effects, and the like required to the power semiconductor device 100.

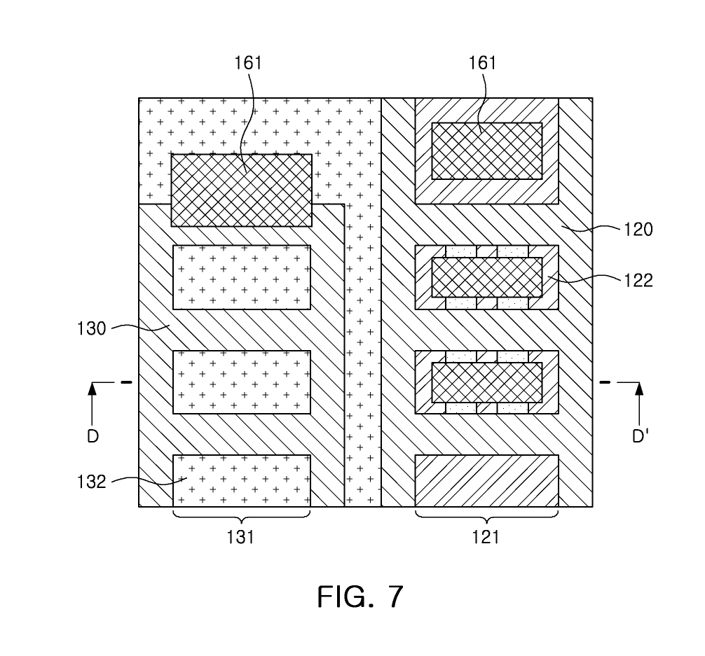

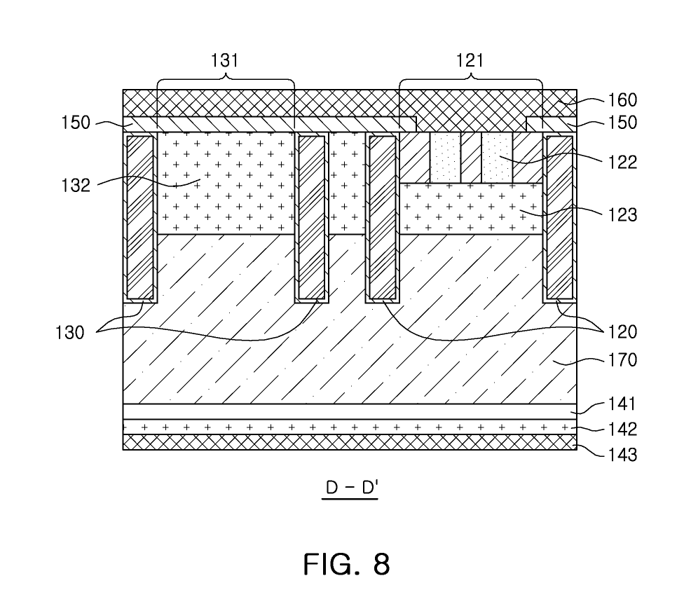

FIG. 7 is a plan view of a power semiconductor device 100 according to a fourth exemplary embodiment of the present disclosure and FIG. 8 is a cross-sectional view taken along line D-D′ after an interlayer insulating film 150 and an emitter metal layer 160 are disposed on the power semiconductor device 100 of FIG. 7.

Specifically, FIG. 7 is a plan view illustrating an emitter metal layer connecting part 161 that is a region having the emitter metal layer 160 connected thereto in the power semiconductor device 100 in which the gate 120, the dummy gate 130, the active part 121, and the inactive part 131 are disposed.

Referring to FIGS. 7 and 8, the power semiconductor device 100 according to an exemplary embodiment of the present disclosure may have an interlayer insulating film 150 disposed on an upper portion of the gate 120 to thereby prevent a connection between the gate 120 and the emitter metal layer 160. Since the interlayer insulating film 150 is disposed on a portion of the upper portion of the dummy gate 130, the portion of the upper portion of the dummy gate 130 may be connected to the emitter metal layer 160. The portion of the upper portion of the active part 121 may be connected to the emitter metal layer 160.

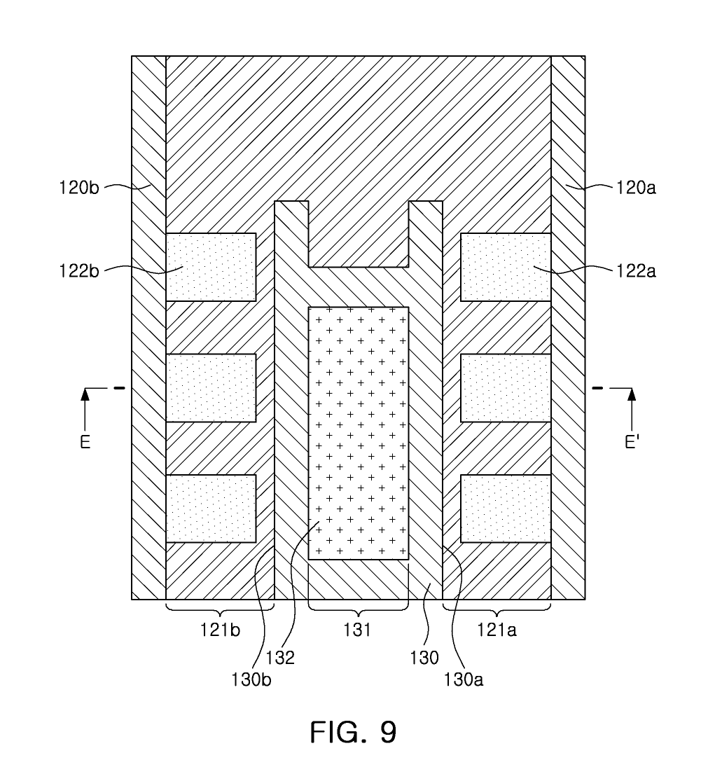

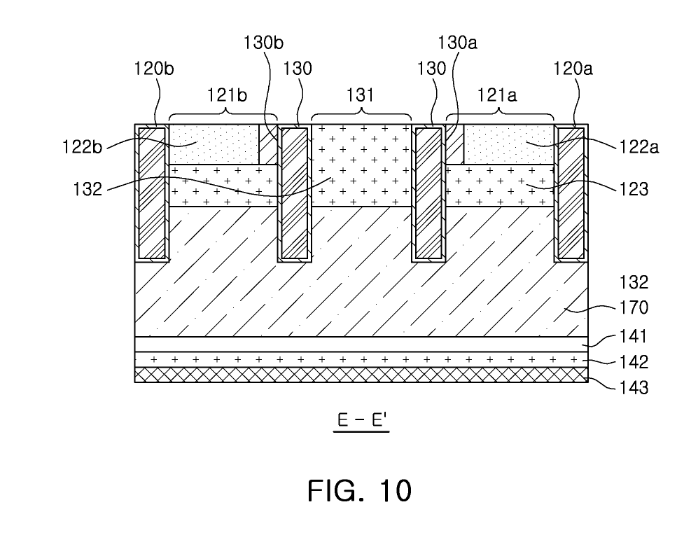

FIG. 9 is a plan view of a power semiconductor device 100 according to a fifth exemplary embodiment of the present disclosure, and FIG. 10 is a cross-sectional view taken along line E-E′ of the power semiconductor device 100 of FIG. 9.

Referring to FIGS. 9 and 10, the power semiconductor device 100 according to an exemplary embodiment of the present disclosure may include an n-drift part 170, a dummy gate 130 disposed in an upper portion of the n-drift part 170, a first gate 120a disposed to be spaced apart from a first external surface 130a of the dummy gate, a first active part 121a disposed in a region between the first external surface 130a of the dummy gate and the first gate 120a, a first emitter part 122a disposed in the first active part 121a and disposed to be in contact with the first gate 120a, an inactive part 131 disposed in a region surrounded by an internal surface of the dummy gate 130, a floating part 132 disposed in the inactive part 131, a second gate 120b disposed to be spaced apart from a second external surface 130b of the dummy gate, a second active part 121b disposed in a region between the second external surface 130b of the dummy gate and the second gate 120b, and a second emitter part 122b disposed in the second active part 121b and disposed to be in contact with the second gate 120b.

According to an exemplary embodiment shown in FIGS. 9 and 10, a plurality of active parts 121 and a plurality of gates 120 may be disposed while having one inactive part 131 therebetween. By the above-mentioned configuration, an integration degree of the power semiconductor device 100 may be increased and an efficient disposition for decreasing parasitic capacitance and conduction loss may be performed.

The first gate 120a may be disposed to be spaced apart from and in parallel with the first external surface 130a that is one surface of external surfaces of the dummy gate 130 surrounding the inactive part 131, and may form the first active part 121a in the region between the first external surface 130a of the dummy gate and the first gate 120a. The first emitter part 122a may be formed by implanting n-type impurities into a portion of the first active part 121a.

When an external surface of the dummy gate 130 in a direction different from the first external surface 130a of the external surfaces of the dummy gate 130 surrounding the inactive part 131 is defined as a second external surface 130b, the second gate 120b may be disposed to be spaced apart from and in parallel with the second external surface 130b of the dummy gate. The second external surface 130b of the dummy gate may be a surface facing the first external surface 130a of the dummy gate, but is not limited to what is illustrated in FIGS. 9 and 10 and may be a surface in contact with the first external surface 130a of the dummy gate at a 90° angle.

The second active part 121b may be disposed in the region between the second external surface 130b of the dummy gate and the second gate 120b. The second emitter part 122b may be formed by implanting n-type impurities into a portion of the second active part 121b.

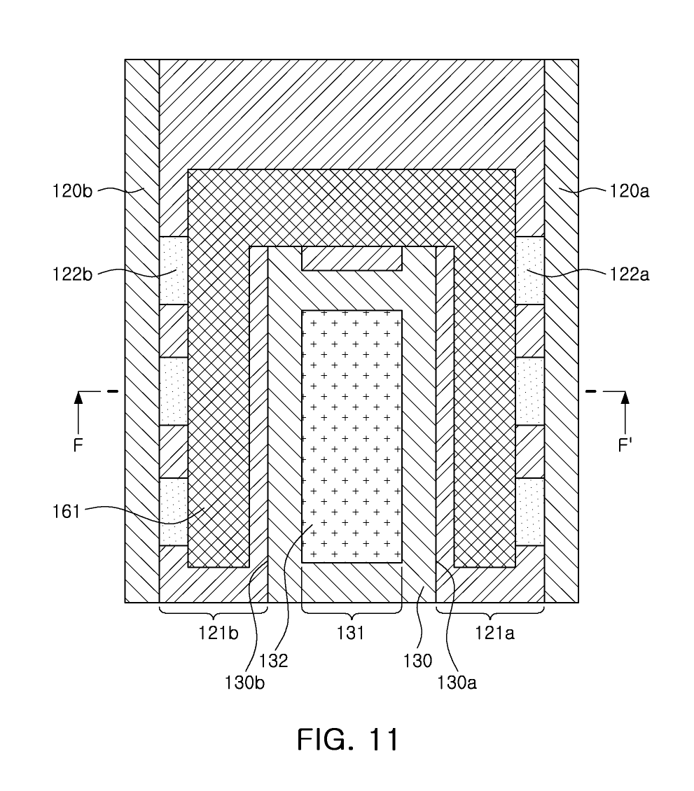

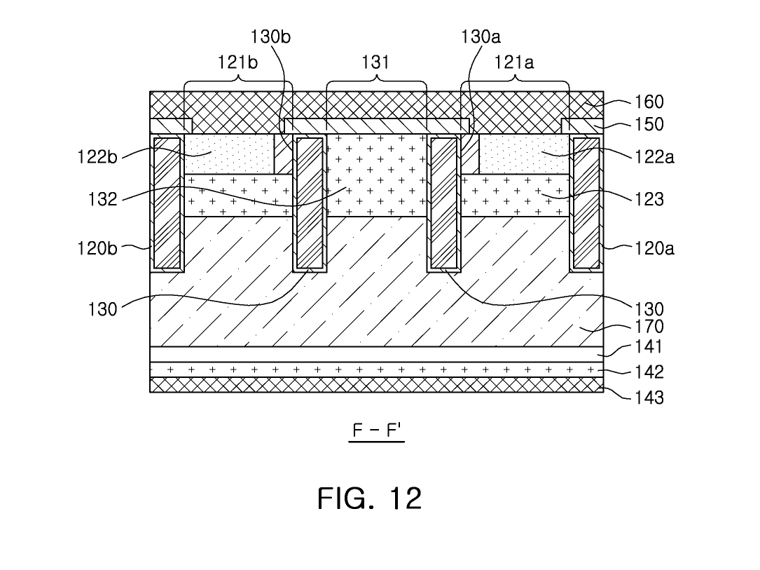

FIG. 11 is a plan view of a power semiconductor device 100 according to a sixth exemplary embodiment of the present disclosure and FIG. 12 is a cross-sectional view taken along line F-F′ after an interlayer insulating film 150 and an emitter metal layer 160 are disposed on the power semiconductor device 100 of FIG. 11.

Specifically, FIG. 11 is a plan view illustrating an emitter metal layer connecting part 161 that is a region having the emitter metal layer 160 connected thereto in the power semiconductor device 100 in which the first and second gates 120a and 120b, the dummy gate 130, the first and second active parts 121a and 121b, and the inactive part 131 are disposed.

Referring to FIGS. 11 and 12, the power semiconductor device 100 according to an exemplary embodiment of the present disclosure may have an interlayer insulating film 150 disposed on upper portions of the first and second gates 120a and 120b to thereby prevent connections between the first and second gates 120a and 120b and the emitter metal layer 160. Since the interlayer insulating film 150 is disposed on a portion of the upper portion of the dummy gate 130, the portion of the upper portion of the dummy gate 130 may be connected to the emitter metal layer 160. A portion of upper portions of the first and second active parts 121a and 121b may be connected to the emitter metal layer 160.

As set forth above, according to the exemplary embodiments of the present disclosure, the power semiconductor device may decrease the generation of parasitic capacitance, operate in a high withstand voltage, and decrease the conduction loss.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
an n-drift part;
a gate disposed in an upper portion of the n-drift part;
an active part disposed in contact with the gate;
an emitter part disposed in the active part and in contact with the gate;
an inactive part spaced apart from the active part;
a floating part disposed in the inactive part; and
a dummy gate disposed to enclose the inactive part in order to prevent a hole pass from occurring between the active part and the inactive part.

2. The power semiconductor device of claim 1, wherein the active part is disposed in a region surrounded by the gate.

3. The power semiconductor device of claim 1, further comprising:
an interlayer insulating film disposed on upper portions of the floating part and the gate; and
an emitter metal layer disposed on upper portions of the active part and the dummy gate, and electrically connected to the active part and the dummy gate.

4. The power semiconductor device of claim 1, wherein the emitter part is an n-type.

5. The power semiconductor device of claim 1, wherein the emitter part is provided in plural.

6. The power semiconductor device of claim 1, wherein the floating part is a p-type.

7. The power semiconductor device of claim 1, further comprising a p-type part disposed below the emitter part.

8. The power semiconductor device of claim 7, wherein depths in a width direction of the n-drift part of the gate and the dummy gate are disposed to be deeper than depths in which the p-type part and the floating part are disposed.

9. The power semiconductor device of claim 1, further comprising a collector electrode disposed below the n-drift part.

10. The power semiconductor device of claim 9, further comprising an n-buffer layer and a p-collector layer disposed between the n-drift part and the collector electrode.

11. The power semiconductor device of claim 1, wherein the active part is disposed in a region between the gate and the dummy gate.

12. The power semiconductor device of claim 11, wherein the emitter part is disposed to be spaced apart from the dummy gate.

13. A power semiconductor device comprising:
an n-drift part;
an inactive part disposed in an upper part of the n-drift part;
a floating part disposed in the inactive part;
a dummy gate disposed to surround the inactive part;
a first gate disposed to be spaced apart from a first external surface of the dummy gate;
a first active part disposed in a region between the first external surface of the dummy gate and the first gate;
a first emitter part disposed in the first active part and disposed to be in contact with the first gate;
a second gate disposed to be spaced apart from a second external surface of the dummy gate;
a second active part disposed in a region between the second external surface of the dummy gate and the second gate;
a second emitter part disposed in the second active part and disposed to be in contact with the second gate.
